(19) United States
(12) Patent Application Publication
(10) Pub. No.: US 2024/0213228 A1
(43) Pub. Date: Jun. 27, 2024

(54) DISPLAY DEVICE

(71) Applicant: LG DISPLAY CO., LTD., SEOUL (KR)

(72) Inventors: Minseok KIM, Seoul (KR); Jongsung KIM, Seoul (KR); Yongmin HA, Seoul (KR)

(73) Assignee: LG DISPLAY CO., LTD., SEOUL (KR)

(21) Appl. No.: 18/387,079

(22) Filed: Nov. 6, 2023

(30) Foreign Application Priority Data
Dec. 27, 2022 (KR) 10-2022-0185765

(51) Int. Cl. H01L 25/075; H01L 33/62

(52) U.S. Cl. CPC H01L 25/0753; H01L 33/62

(57) ABSTRACT

A display device includes a wiring substrate on which a plurality of link wire lines are disposed; a plurality of display units including a plurality of light-emitting elements and a plurality of signal lines, wherein the plurality of display units are disposed on the wiring substrate and are spaced apart from each other; a reflective layer positioned between the wiring substrate and the plurality of display units; and a plurality of bonding members positioned between the reflective layer and the wiring substrate to electrically connecting the plurality of link wire lines and the plurality of signal lines to each other.

### CROSS-REFERENCE TO RELATED APPLICATION

This application claims the priority of Korean Patent Application No. 10-2022-0185765 filed on Dec. 27, 2022, which is hereby incorporated by reference in its entirety.

### BACKGROUND

### Field of the Disclosure

The present disclosure relates to a display device, and more particularly, to a display device capable of preventing reflection of external light to improve light efficiency.

### Description of the Background

A display device is applied to various electronic devices such as TVs, mobile phones, laptops, and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with the built-in light source, and may be implemented as a flexible display device that may be folded, bent, or rolled.

The display device having the self-light-emitting element may include, for example, an organic light-emitting display device (OLED) including a light-emitting layer made of an organic material, or a micro-LED display device (micro light-emitting diode display device) including a light-emitting layer made of an inorganic material. In this regard, the organic light-emitting display device does not require a separate light source. However, due to material characteristics of the organic material that is vulnerable to moisture and oxygen, a defective pixel easily occurs in the organic light-emitting display device due to an external environment.

On the contrary, the micro-LED display device includes the light-emitting layer made of the inorganic material that is resistant to moisture and oxygen and thus is not affected by the external environment and thus has high reliability and has a long lifespan compared to the organic light-emitting display device.

Since the micro-LED display device is resistant to the external environment, the micro-LED display device does not require a protective structure such as a sealing material, and various types of materials may be used as a material of a substrate of the device, thereby implementing a flexible display device with a thinner structure than that of the organic light-emitting display device. Accordingly, a plurality of micro-LED display devices may be arranged in first and second directions intersecting each other to implement a large-area tiling display apparatus.

When the tiling display apparatus is implemented by arranging a plurality of micro-LED display devices in the first and second directions intersecting each other, a structure for blocking a non-display area surrounding a display area from the user's field of view, for example, a bezel, is disposed. However, as a width of the bezel increases, the user may recognize the bezel to lower image immersion. Thus, research is being conducted to form a minimum bezel area.

### SUMMARY

Accordingly, the present disclosure is directed to a display device that substantially obviates one or more of problems due to limitations and disadvantages described above.

More specifically, the present disclosure is to provide a large-area display device by arranging a plurality of display units on an upper surface of a wiring substrate.

In addition, the present disclosure is to provide a transparent display device that prevents external light from being reflected from a metallic material of a plurality of link wire lines disposed on the wiring substrate and thus prevents reflectance from increasing.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

The present disclosure is not limited to the above-mentioned. Other advantages according to the present disclosure that are not mentioned may be understood based on following descriptions, and may be more clearly understood based on aspects according to the present disclosure. Further, it will be easily understood that the purposes and advantages according to the present disclosure may be realized using means shown in the claims or combinations thereof.

To achieve these and other advantages and in accordance with the present disclosure, as embodied and broadly described, a display device includes a wiring substrate on which a plurality of link wire lines are disposed; a plurality of display units including a plurality of light-emitting elements and a plurality of signal lines, respectively, wherein the plurality of display units are disposed on the wiring substrate and are spaced apart from each other; a reflective layer positioned between the wiring substrate and the plurality of display units; and a plurality of bonding members positioned between the reflective layer and the wiring substrate to electrically connecting the plurality of link wire lines and the plurality of signal lines to each other.

According to the aspect of the present disclosure, the plurality of display units may be disposed on the upper surface of the wiring substrate and may be arranged to overlap the upper surface of the wiring substrate, such that a transparent display device with a large area may be implemented.

Moreover, the wiring substrate and each of the plurality of display units are electrically connected and are bonded to each other using the bonding member. Thus, a plurality of processes for forming a side surface line may be omitted such that the process optimization may be realized.

Moreover, the reflective layer or the spacer pattern including a metal material with high reflectance may be disposed on top of the display unit. Thus, the light may be directed toward the display unit such that the reflectance of the external light may be reduced. Accordingly, the light efficiency of the display device may be improved. Thus, the display device may operate at a low power level.

Effects of the present disclosure are not limited to the effects mentioned above, and other effects not mentioned will be clearly understood by those skilled in the art from the descriptions below.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a schematic plan view of a display device according to an aspect of the present disclosure.

FIG. 2 is a schematic plan view of a wiring substrate according to an aspect of the present disclosure.

FIG. 3 is a cross-sectional view taken along line 3-3 in FIG. 2.

FIG. 4 is a schematic enlarged plan view of area 4 in FIG. 1.

FIG. 5 is a cross-sectional view taken along line 5-5 in FIG. 4.

FIG. 6 to FIG. 8 are diagrams for illustrating a display device according to an aspect of the present disclosure.

FIG. 9 to FIG. 11 are diagrams for illustrating a display device according to another aspect of the present disclosure.

FIG. 12 to FIG. 14 are diagrams for illustrating a display device according to still another aspect of the present disclosure.

### DETAILED DESCRIPTION

Advantages and features of the present disclosure, and a method of achieving the advantages and features will become apparent with reference to aspects described later in detail together with the accompanying drawings. However, the present disclosure is not limited to the aspects as disclosed under, but may be implemented in various different forms. Thus, these aspects are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various aspects are illustrated and described further below. It will be understood that the description herein is not intended to limit the claims to the specific aspects described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating aspects of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is directed to the purpose of describing particular aspects only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is indicated.

When a certain aspect may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various aspects of the present disclosure may be partially or entirely combined with each other, and may be technically associated with each other or operate with each other. The aspects may be implemented independently of each other and may be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

The features of the various aspects of the present disclosure may be partially or entirely combined with each other, and may be technically associated with each other or operate with each other. The aspects may be implemented independently of each other and may be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “aspects,” “examples,” “aspects, and the like should not be construed such that any aspect or design as described is superior to or advantageous over other aspects or designs.

Further, the term ‘or’ means ‘inclusive or’ rather than ‘exclusive or’. That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating aspects.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to each aspect of the present disclosure will be described with reference to the accompanying drawings.

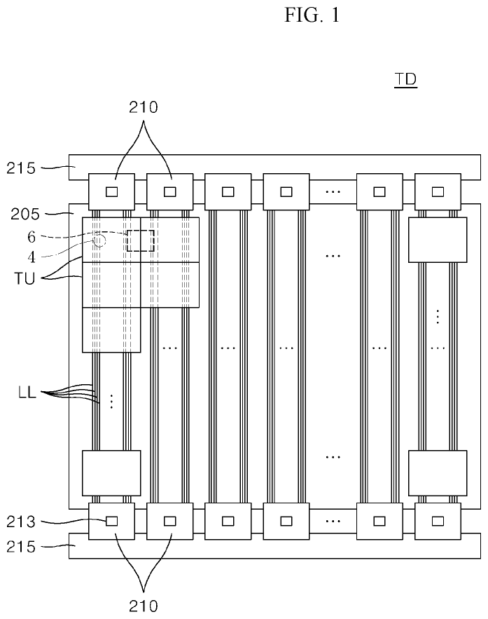

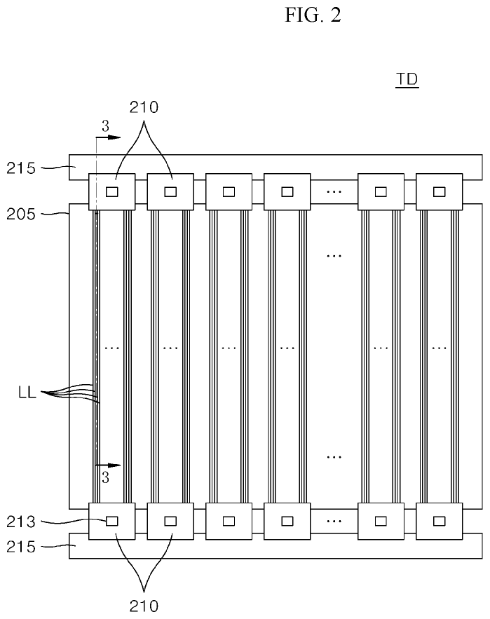

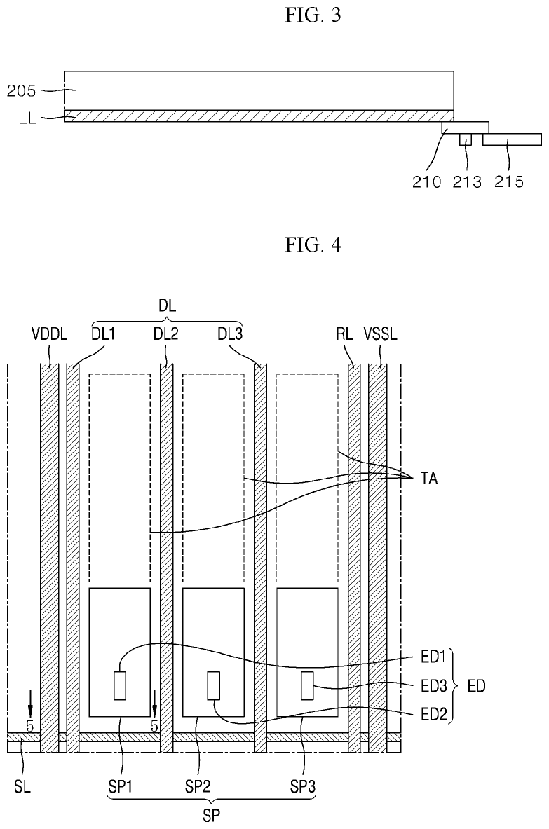

FIG. 1 is a schematic plan view of a display device according to an aspect of the present disclosure. FIG. 2 is a schematic plan view of a wiring substrate according to one aspect of the present disclosure. FIG. 3 is a cross-sectional view of 3 in FIG. 2.

In FIG. 1, for convenience of illustration, among components of a display device TD, only a wiring substrate 205, a plurality of link wire lines LL, a plurality of circuit films 210 on which a plurality of integrated circuit chips 213 are respectively disposed, printed circuit boards 215, and a plurality of display units TU are shown. FIG. 2 shows components except for the plurality of display units TU among the components shown in FIG. 1.

Referring to FIGS. 1 to 3, the tiling display device TD according to one aspect of the present disclosure may include the wiring substrate 205, and the plurality of display units TU arranged on the wiring substrate 205. The display units TU may be arranged along each of a first direction and a second direction intersecting the first direction. In this regard, the first direction may be a horizontal direction, and the second direction may be a vertical direction. The wiring substrate 205 may include glass or transparent plastic.

The plurality of link wire lines LL may be disposed on the wiring substrate 205. The plurality of link wire lines LL may extend along one direction of the wiring substrate 205. A driver may be disposed on each of both opposing side ends of the wiring substrate 205. The driver may include each of the printed circuit boards 215 connected to each of the circuit films 210 on which each of the integrated circuit chips 213 is mounted. Each of the circuit films 210 is connected to each of ends of the link wire lines. The driver may transmit various signals to sub-pixels of each display unit TU. For example, the signals transmitted to the sub-pixels may include a high-potential voltage, a low-potential voltage, a scan signal, or a data signal. In an aspect of the present disclosure, a configuration in which each driver including each of the printed circuit boards 215 connected to each of the circuit films 210 on which each of the integrated circuit chips 213 is mounted is disposed at each of both opposing side ends of the wiring substrate 205 is illustrated. However, the present disclosure is not limited thereto.

The plurality of link wire lines LL may deliver various signals delivered from the driver to the plurality of signal lines disposed in each of the display units TU. For example, the signal lines may include, but are not limited to, a high-potential voltage line, a low-potential voltage line, a scan line, and a data line.

Each of the plurality of display units TU disposed on the wiring substrate 205 may be connected to the wiring substrate 205 via an electrical connection between each of a plurality of signal lines and the plurality of link wire lines LL disposed in the wiring substrate 205. In this regard, the plurality of link wire lines LL may be disposed to overlap the plurality of display units TU, respectively, and may not be exposed to the outside. As a result, an area size of the circuit area in which the plurality of link wire lines LL are disposed may be reduced and thus the display area may be increased.

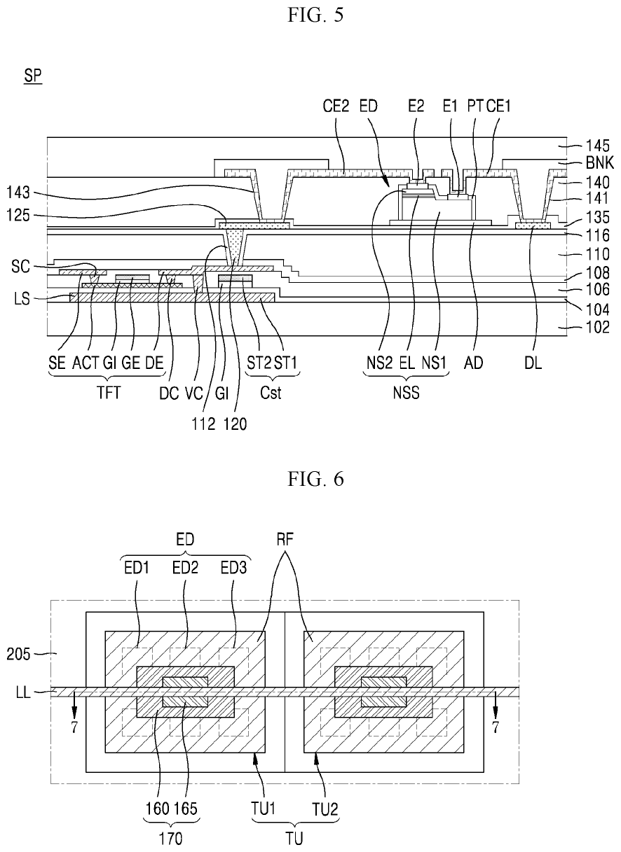

A plurality of pixels may be disposed in each of the plurality of display units TU. A light-emitting element and a driving circuit including a transistor for driving the light-emitting element may be disposed in each of the plurality of pixels. This will be described with reference to FIG. 4 and FIG. 5 below.

FIG. 4 is a schematic enlarged plan view of area 4 of FIG. 1 of the display device according to one aspect of the present disclosure. FIG. 5 is a cross-sectional view taken along line 5-5 in FIG. 4. FIG. 4 is an enlarged plan view of a portion of an area corresponding to a pixel disposed in a display unit.

Referring to FIG. 4, each of the plurality of pixels SP may include a plurality of sub-pixels SP1, SP2, and SP3. The plurality of sub-pixel SP1, SP2, and SP3 may include the first sub-pixel SP1, the second sub-pixel SP2, and the third sub-pixel SP3.

Each of the sub-pixels SP1, SP2, and SP3 may include a light-emitting area and a circuit area for driving the light-emitting area. The light-emitting area may include a first light-emitting element ED1, a second light-emitting element ED2, and a third light-emitting element ED3 emitting light of different colors of red (R), green (G), and blue B, respectively. The light-emitting area may refer to an area in which light emitted from the first to third light-emitting elements ED1, ED2, and ED3 may be emitted to the outside. The light-emitting area may further include a white light-emitting element emitting white light. A light-emitting element according to an aspect of the present disclosure may be embodied as a micro-LED (a Micro Light Emitting Diode). The micro-LED may be a LED made of an inorganic material, and may refer to a light-emitting element with a thickness of 100 μm or smaller or free of a growth substrate for growing the LED.

The circuit area refers to an area other than the light-emitting area. In the circuit area, circuit elements such as a thin-film transistor and a storage capacitor, etc. for driving the first light-emitting element ED1, the second light-emitting element ED2, or the third light-emitting element ED3 may be disposed.

Each of a plurality of transmissive areas TA may be defined in each of the plurality of pixels. The transmissive area TA may be an area in which a non-transparent material or a reflective material is not disposed. The tiling display device TD according to an aspect of the present disclosure may secure transmittance due to the transmissive area TA. Thus, the tiling display device TD may be a transparent display device through which an object disposed of rear of the tiling display device TD (refer to FIG. 1) may be recognized by a viewer in front of the device.

A plurality of signal lines may be disposed on a base substrate 102. The plurality of signal lines may include a high-potential voltage line VDDL, a low-potential voltage line VSSL, a reference voltage line RL, a data line DL, and a scan line SL.

Each of the high-potential voltage line VDDL and the low-potential voltage line VSSL may supply a driving power for driving the first light-emitting element ED1, the second light-emitting element ED2, or the third light-emitting element ED3. The reference voltage line RL may deliver a reference voltage to each of the plurality of sub-pixels SP1, SP2, and SP3.

The data line DL may include a first data line DL1, a second data line DL2, and a third data line DL3. Each of the plurality of data lines DL1, DL2, and DL3 may be disposed on one side of each of the plurality of sub-pixels SP1, SP2, and SP3 and may extend in a column direction, and may supply the data signal to each of the plurality of sub-pixels SP1, SP2, and SP3.

The scan line SL may extend in a row direction intersecting the data line DL and may supply the scan signal to each of the plurality of sub-pixels SP1, SP2, and SP3.

The signal lines including the high-potential voltage line VDDL, the low-potential voltage line VSSL, the reference voltage line RL, the data line DL, and the scan line SL may be connected to the wiring substrate 205 via electrical connections thereof to the plurality of link wire lines LL disposed in the wiring substrate 205, respectively. For example, the signal lines may be electrically connected to the link wire line LL on the wiring substrate 205 via a bonding member. A configuration in which the bonding member is disposed will be described later with reference to FIG. 6.

Hereinafter, referring to FIG. 5, one sub-pixel among the plurality of sub-pixels SP1, SP2, and SP3 disposed on the display unit will be described. The sub-pixels SP1, SP2, and SP3 may include the same component.

Referring to FIG. 5, the sub-pixel SP1 according to one aspect of the present disclosure may include a base substrate 102, and a thin-film transistor TFT, a storage capacitor Cst, and various lines disposed on the base substrate 102. The thin-film transistor TFT may drive the light-emitting element ED, and the storage capacitor Cst may store a voltage therein so that the light-emitting element ED continues to maintain the same state during one frame. The base substrate 102 may be made of a transparent material including glass or plastic.

A light-blocking layer LS may be disposed on the base substrate 102. The light-blocking layer LS may prevent light incident from the base substrate 102 from invading an active layer ACT of a transistor to reduce leakage current. For example, the light-blocking layer LS may be disposed under the active layer ACT of the thin-film transistor TFT functioning as a driving transistor to prevent light from being incident to the active layer ACT.

A buffer layer 104 is disposed on the light-blocking layer LS. The buffer layer 104 may block impurities or moisture flowing through the base substrate 102. The buffer layer 104 may include, for example, an insulating material such as silicon oxide (SiOx) and silicon nitride (SiNx).

The thin-film transistor TFT is disposed on the buffer layer 104. The thin-film transistor TFT may include the semiconductor layer ACT, a gate electrode GE, a source electrode SE, and a drain electrode DE. A gate insulating layer GI may be disposed between the semiconductor layer ACT and the gate electrode GE.

The semiconductor layer ACT may include an active area overlapping the gate electrode GE to constitute a channel, and a source area and a drain area located respectively on both opposing sides of the active area disposed therebetween. An interlayer insulating film 106 is disposed on the gate electrode GE. The interlayer insulating film 106 may receive a source contact SC and a drain contact DC therein. The source contact SC and the drain contact DC may contact portions of surfaces of the source area and the drain area of the semiconductor layer ACT, respectively. The source contact SC and the drain contact DC may be respectively electrically connected to the source electrode SE and the drain electrode DE located on the interlayer insulating film 106. Thus, the source electrode SE and the drain electrode DE may be respectively electrically connected to the source and drain areas of the semiconductor layer ACT via the source contact SC and the drain contact DC. Each of the source electrode SE and the drain electrode DE may be made of a conductive material such as copper (Cu), aluminum (Al), molybdenum (Mo), nickel (Ni), titanium (Ti), and chromium (Cr), or an alloy thereof. However, the present disclosure is not limited thereto.

The storage capacitor Cst may include a first capacitor electrode ST1 and a second capacitor electrode ST2. The first capacitor electrode ST1 may be disposed between the base substrate 102 and the buffer layer 104. The first capacitor electrode ST1 may be formed integrally with the light-blocking layer LS. The buffer layer 104 and the gate insulating layer GI may be disposed on the first capacitor electrode ST1 and may act as a dielectric layer. The second capacitor electrode ST2 may be disposed on the gate insulating layer GI. The second capacitor electrode ST2 may be made of the same material as that of the gate electrode GE.

A first passivation layer 108 is disposed on the source electrode SE and the drain electrode DE. The first passivation layer 108 serves to protect the thin-film transistor TFT and may include an insulating material. A first planarization layer 110 is disposed on the first passivation layer 108. The first planarization layer 110 serves to remove a surface step caused by an underlying component such as the thin-film transistor TFT. The first planarization layer 110 may include a photoactive compound (PAC). However, the present disclosure is not limited thereto.

The first planarization layer 110 may have a contact-hole 112 defined therein exposing a portion of a surface of the drain electrode DE. The contact-hole 112 may extend through the first planarization layer 110 and the first passivation layer 108 to expose the portion of the surface of the drain electrode DE.

A second passivation layer 116 including an insulating material may be disposed on the first planarization layer 110. A via contact 120 may fill the contact-hole 112. A connection electrode 125 connected to the via contact 120 may be disposed on the second passivation layer 116.

One surface of the via contact 120 may contact the drain electrode DE and the other surface thereof may contact the connection electrode 125. Moreover, the drain electrode DE may be electrically connected to the light-blocking layer LS via a via hole VC extending through the interlayer insulating film 106 and the buffer layer 104.

A signal line may be disposed on the second passivation layer 116. The signal line may be coplanar with the connection electrode 125. The signal line may include a plurality of signal lines. For example, the plurality of signal lines may include a plurality of scan lines SL, a plurality of high-potential power lines VDDL, a plurality of data lines DL, and a plurality of reference voltage lines RL. In an aspect of the present disclosure, the data line DL is shown for convenience of illustration. However, the present disclosure is not limited thereto. The plurality of signal lines may be disposed on the base substrate 102 and may be coplanar with each other. Moreover, the plurality of signal lines may be made of the same material as that of the via contact 120.

A third passivation layer 135 covering the connection electrode 125, the data line DL, and the second passivation layer 116 is disposed. The third passivation layer 135 may not cover a portion of an upper surface of each of the connection electrode 125 and the data line DL to be exposed.

An adhesive layer AD is disposed on the third passivation layer 122. The adhesive layer AD serves to adhere the light-emitting element ED. The adhesive layer AD may be made of a heat curable material or a light curable material. However, the present disclosure is not limited thereto.

A light-emitting element ED may be disposed on the adhesive layer AD. The light-emitting element ED according to an aspect of the present disclosure may be embodied as a micro-LED. The micro-LED may be an LED made of an inorganic material and may be understood as a light-emitting element of 100 μm or smaller. Moreover, in an aspect of the present disclosure, an example in which the light-emitting element ED is embodied as a horizontal type micro-LED is described. However, the present disclosure is not limited thereto. For example, the light-emitting element may be embodied as a vertical type micro-LED, a flip-chip shaped micro-LED, or a nanorod-shaped micro-LED.

The light-emitting element ED may include a nitride semiconductor structure NSS, a first electrode E1 and a second electrode E2. The nitride semiconductor structure NSS may include a first semiconductor layer NS1, an active layer EL disposed on one side of an upper surface of the first semiconductor layer NS1, and a second semiconductor layer NS2 disposed on the active layer EL. The first electrode E1 is disposed on the other side of the upper surface of the first semiconductor layer NS1 where the active layer EL is not located. The second electrode E2 is disposed on the second semiconductor layer NS2.

The first semiconductor layer NS1 is a layer for supplying electrons to the active layer EL, and may include a nitride semiconductor containing a first conductivity type impurity. For example, the first conductivity-type impurity may include an N-type impurity. The active layer EL disposed on one side of the upper surface of the first semiconductor layer NS1 may include a multi-quantum well (MQW) structure. The second semiconductor layer NS2 is a layer for injecting holes into the active layer EL. The second semiconductor layer NS2 may include a nitride semiconductor containing a second conductivity type impurity. For example, the second conductivity type impurity may include a P-type impurity.

A protective layer pattern PT may cover an outer surface of the light-emitting element ED. The protective layer pattern PT plays a role of supplementing the characteristics of the element by preventing damage that may occur on the side surface of the nitride semiconductor structure NSS in a dry etching process to form the nitride semiconductor structure NSS.

The light-emitting element ED may be covered with a second planarization layer 140. The second planarization layer 140 may have a thickness sufficient to planarize a stepped upper surface caused by the underlying circuit elements. The second planarization layer 140 may have opening holes 141 and 143 defined therein. The opening holes 141 and 143 may include the first opening hole 141 and the second opening hole 143. Moreover, the second planarization layer 140 may not cover a portion of an upper surface of each of the first electrode E1 and the second electrode E2 of the light-emitting element ED to be exposed. The first electrode E1 and the second electrode E2 may be electrically connected to a first line electrode CE1 and a second line electrode CE2, respectively.

The first line electrode CE1 may extend along and on an exposed surface of the first opening hole 141. The second line electrode CE2 may extend along and on an exposed surface of the second opening hole 143. The first line electrode CE1 may be electrically connected to the data line DL. The second line electrode CE2 may be electrically connected to the drain electrode DE via the connection electrode 125.

The first line electrode CE1 and the second line electrode CE2 may be disposed in the same layer and made of the same conductive material. In one example, each of the first line electrode CE1 and the second line electrode CE2 may include a transparent metal oxide such as indium-tin-oxide (ITO) and indium-zinc-oxide (IZO). However, the present disclosure is not limited thereto.

A bank BNK may be disposed on the second planarization layer 140. The bank BNK may include an opaque material. However, the present disclosure is not limited thereto. In one example, the bank BNK may be formed to cover the first line electrode CE1 and the second line electrode CE21. The first opening hole 141 and the second opening hole 143 may be filled with a material constituting the bank BNK. Moreover, the bank BNK may be disposed in an area surrounding the light-emitting element ED, except for an area where the light-emitting element ED is disposed.

A sealing layer 145 may be disposed on the second planarization layer 140 and the bank BNK. The sealing layer 145 may prevent penetration of moisture or impurities into the light-emitting element ED.

The plurality of display units TU including the plurality of sub-pixels SP including these various components may be disposed on the wiring substrate 205 and may be arranged along the first direction and the second direction intersecting the first direction, as shown in FIG. 1. In this regard, the first direction may be a transverse direction. The second direction may be a longitudinal direction.

The plurality of display units TU arranged on the wiring substrate 205 may be connected to the wiring substrate 205 via electrical connections between the plurality of signal lines and the plurality of link wire lines LL arranged on the wiring substrate 205, respectively. In this regard, the plurality of link wire lines LL may overlap the plurality of display units TU and may not be exposed to the outside. Each of the plurality of link wire line LL and each of the plurality of display unit TU may be electrically connected to each other via a bonding member having electrical conductivity.

Hereinafter, a configuration in which a plurality of display units are disposed on a wiring substrate will be described with reference to drawings.

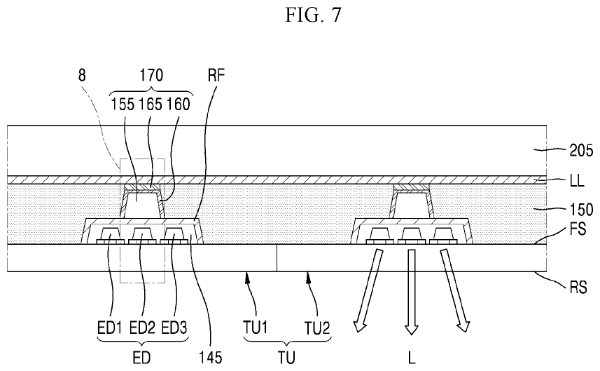

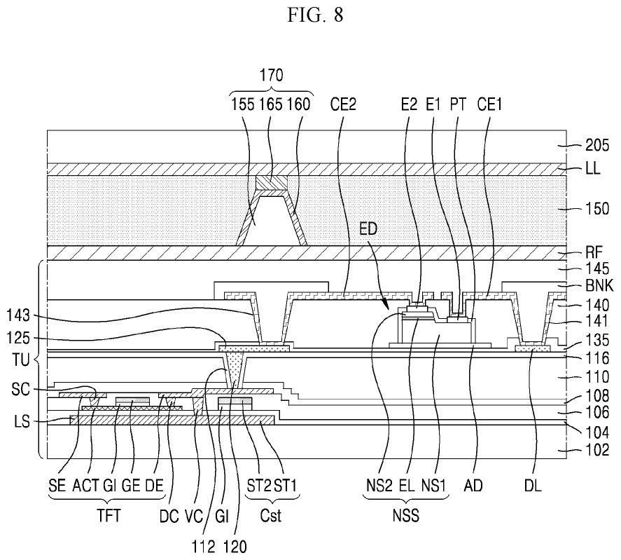

FIG. 6 to FIG. 8 are diagrams for illustrating a display device according to an aspect of the present disclosure. In this regard, FIG. 6 is a schematic enlarged plan view of an area 6 in FIG. 1. FIG. 7 is a cross-sectional view taken along line 7-7 in FIG. 6. FIG. 8 is an enlarged cross-sectional view of an area 8 in FIG. 7. Since the display unit TU in FIG. 8 is the same as the display unit TU in FIG. 5, the same components may be briefly described, or descriptions thereof may omitted.

Referring to FIG. 6 to FIG. 8, display units TU1 and TU2 are disposed on the wiring substrate 205. The display unit TU may include the first display unit TU1 and the second display unit TU2 arranged to be adjacent to each other in one direction. In the drawing, only a configuration in which two display units TU1 and TU2 are arranged is presented for convenience of illustration. However, the present disclosure is not limited thereto. For example, another display unit may be disposed adjacent to one side of each of the two display units.

A sub-pixel including the light-emitting element ED and a thin-film transistor TFT for driving the light-emitting element ED may be disposed in each of the first display unit TU1 and the second display unit TU2. FIG. 8 shows one light-emitting element ED and one thin-film transistor TFT for convenience of illustration. However, the present disclosure is not limited thereto. The light-emitting element ED may include the first light-emitting element ED1, the second light-emitting element ED2 and the third light-emitting element ED3. The first light-emitting element ED1, the second light-emitting element ED2, and the third light-emitting element ED3 may emit light of red (R), green (G), and blue (B), respectively.

A reflective layer RF may be disposed on the display unit TU. The reflective layer RF may be disposed on the sealing layer 145 covering the light-emitting element ED. The reflective layer RF serves to reflect the light emitted from the light-emitting element ED toward the light-emitting area. The reflective layer RF may include a metal material with high reflectance. For example, a metal material with high reflectance may have a single-layer structure or a stack structure made of any one material selected from aluminum (Al), copper (Cu), silver (Ag), molybdenum (Mo), gold (Au), magnesium (Mg), calcium (Ca), or barium (Ba), or an alloy of at least two thereof.

As the light emitted from the light-emitting element ED is emitted toward the open area defined by the bank BNK, the light may be emitted toward the wiring substrate 205. However, external light may be reflected from the link wire line LL disposed on the wiring substrate 205, and thus light efficiency may be reduced.

Accordingly, in an aspect of the present disclosure, the reflective layer RF is disposed on the display unit TU. Then, as shown in FIG. 7, the light emitted from the light-emitting element ED is reflected from the reflective layer RF disposed on the sealing layer 145 to be directed toward a rear surface RS opposite to a front surface FS of the display unit TU and then may be emitted to the outside. Accordingly, the display device according to an aspect of the present disclosure may have a bottom emission structure. Introducing the bottom emission structure may allow the light efficiency to be improved.

A bonding member 170 may be disposed on the reflective layer RF. The bonding member 170 may include a spacer pattern 155, a conductive connection pattern 160, and an adhesive pattern 165. A lower surface of the spacer pattern 155 may be in contact with the reflective layer RF, and may include a metal material with high reflectance. In one example, the spacer pattern 155 may include the same material as that of the reflective layer RF. Alternatively, the spacer pattern 155 may include a material different from that of the reflective layer RF, but may be made of a metal material having high reflectance.

The spacer pattern 155 may play a role of maintaining a gap between the wiring substrate and the display unit TU. The spacer pattern 155 may have a taper shape in which a lower surface thereof in contact with the reflective layer RF is wider than an upper surface thereof.

An outer surface of the spacer pattern 155 may be covered with the conductive connection pattern 160. For example, the conductive connection pattern 160 may cover the upper surface of the spacer pattern 155 and surround an outer side surface thereof. Moreover, the conductive connection pattern 160 may extend to contact the reflective layer RF. The conductive connection pattern 160 may include, but is not limited to, a conductive material such as copper (Cu), aluminum Al, molybdenum (Mo), nickel (Ni), titanium (Ti), and chromium (Cr), or an alloy thereof.

An adhesive pattern 165 may be disposed on a portion of the conductive connection pattern 160 covering the upper surface of the spacer pattern 155. The adhesive pattern 165 may bonding and fixing the wiring substrate 205 and the display units TU1 and TU2 to each other. Moreover, the adhesive pattern 165 may have electrical conductivity to transmit a signal transmitted to the link wire line LL on the wiring substrate 205 to the display units TU1 and TU2. To this end, the adhesive pattern 165 may include a material that is both electrically conductive and adhesive. For example, the adhesive pattern 165 may include an anisotropic conductive film (ACF). However, the present disclosure is not limited thereto.

The bonding member 170 may be disposed to overlap the plurality of link wire lines LL disposed on the wiring substrate 205 to electrically connect the wiring substrate 205 and each of the plurality of display units TU to each other. The spacer pattern 155 of the bonding member 170 may include a metal material having high reflectance. Accordingly, a path along which the light emitted from the front surface FS of the display unit TU is directed toward the wiring substrate 205 may be changed to a path along which the light emitted from the front surface FS of the display unit TU is directed toward the rear surface RS thereof to increase the amount of light toward the rear surface. Thus, the light efficiency may be improved.

Moreover, the wiring substrate 205 and the plurality of display units TU may be electrically connected to each other via the bonding member 170. Accordingly, a process of forming a line on a side surface of each of the display units TU1 and TU2 adjacent to each other may be omitted, thereby realizing process optimization.

A space between the wiring substrate 205 and the display unit TU may be filled with a filler 150 made of a transparent material. For example, the filler 150 may include a transparent epoxy resin and may be filled in an underfill process. The filler 150 may have a sufficient thickness such that a top face of the filler has the same vertical level as that of a top face of the conductive connection pattern 165 covering the upper surface of the spacer pattern 160 of the bonding member 170. The filler 150 together with the bonding member 170 may fix the wiring substrate 205 and the display unit TU to each other.

In one example, the bonding member 170 may be bonded onto the display unit TU while being disposed on the link wire line LL of the wiring substrate 205. This will be described with reference to the drawings below.

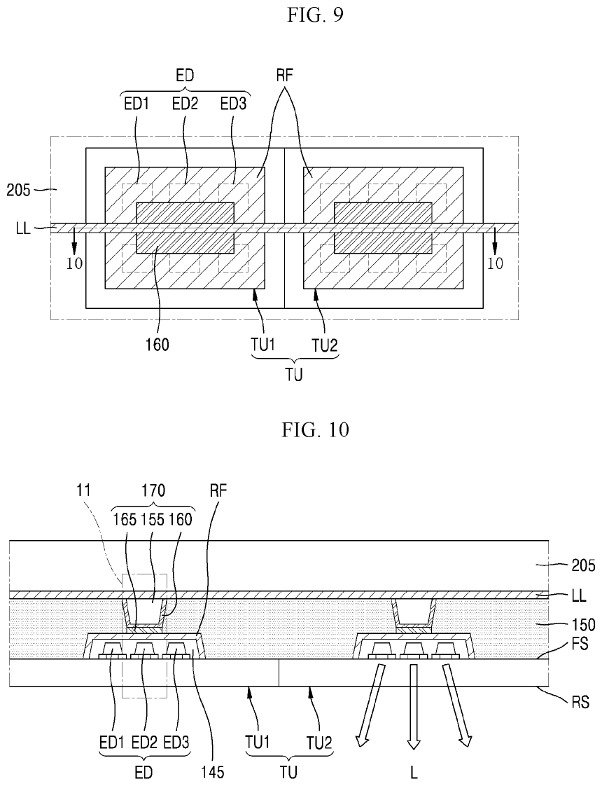

FIG. 9 to FIG. 11 are diagrams for illustrating a display device according to another aspect of the present disclosure. Since the display device according to another aspect of the present disclosure as shown in FIG. 9 to FIG. 11 is the same as the display device in FIG. 8 except for a shape of the bonding member, differences therebetween will be described.

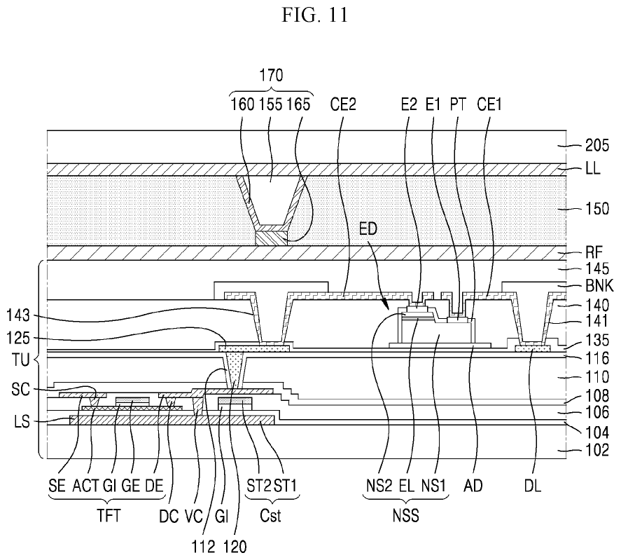

FIG. 9 is a schematic enlarged plan view showing a configuration in which a plurality of display units are disposed on a wiring substrate. FIG. 10 is a cross-sectional view taken along line 10-10 in FIG. 9. FIG. 11 is an enlarged cross-sectional view of an area 11 in FIG. 10. In this regard, since the display unit TU of FIG. 9 to FIG. 11 is the same as the display unit TU according to FIG. 5, the same components may be briefly described or descriptions thereof may be omitted.

Referring to FIG. 9 to FIG. 11, the wiring substrate 205 and the plurality of display units TU1 and TU2 may be bonded and electrically connected to each other via the bonding member 170. The bonding member 170 may overlap the link wire line LL disposed on the wiring substrate 205 and may be bonded thereto.

The bonding member 170 may include the spacer pattern 155, the conductive connection pattern 160, and the adhesive pattern 165. The upper surface of spacer pattern 155 may be in contact with link wire line LL, and may include a metal material with high reflectance. In one example, the spacer pattern 155 may include the same material as that of the reflective layer RF. Alternatively, the spacer pattern 155 may include a material different from that of the reflective layer RF, but may be made of a metal material having high reflectance. The spacer pattern 155 may have a reverse taper shape in which a width of the upper surface thereof in contact with the link wire line LL is larger than that of the lower surface thereof.

An outer side surface and a lower surface of the spacer pattern 155 may be covered with the conductive connection pattern 160. The conductive connection pattern 160 may cover the lower surface of the spacer pattern 155 while surrounding the outer side surface of the spacer pattern 155. Moreover, one surface of the conductive connection pattern 160 may contact the reflective layer RF. The conductive connection pattern 160 may include, but is not limited to, a conductive material such as copper (Cu), aluminum Al, molybdenum (Mo), nickel (Ni), titanium (Ti), and chromium (Cr), or an alloy thereof.

The adhesive pattern 165 may be disposed under the conductive connection pattern 160 covering the lower surface of the spacer pattern 155. The adhesive pattern 165 may bonding and fixing the wiring substrate 205 and the display units TU1 and TU2 to each other. For example, the adhesive pattern 165 may adhere to the reflective layer RF on the display units TU1 and TU2. The adhesive pattern 165 may have electrical conductivity to transmit a signal transmitted to the link wire line LL on the wiring substrate 205 to the display units TU1 and TU2. To this end, the adhesive pattern 165 may include a material that is both electrically conductive and adhesive. For example, the adhesive pattern 165 may include an anisotropic conductive film (ACF). However, the present disclosure is not limited thereto.

In the display device according to another aspect of the present disclosure, the light emitted from the light-emitting element ED is reflected from the reflective layer RF to be directed toward the rear surface RS of the display unit TU and then may be emitted to the outside. Thus, the display device may have a bottom emission structure. Due to this bottom emission structure, the amount of light directed toward the rear surface RS of the display unit TU increases such that the light efficiency may be improved.

FIG. 12 to FIG. 14 are diagrams for illustrating a display device according to still another aspect of the present disclosure. Since the display device according to still another aspect of the present disclosure as shown in FIG. 12 to FIG. 14 is the same as the display device in FIG. 10 except for a shape of the bonding member and the reflective layer, differences therebetween will be described.

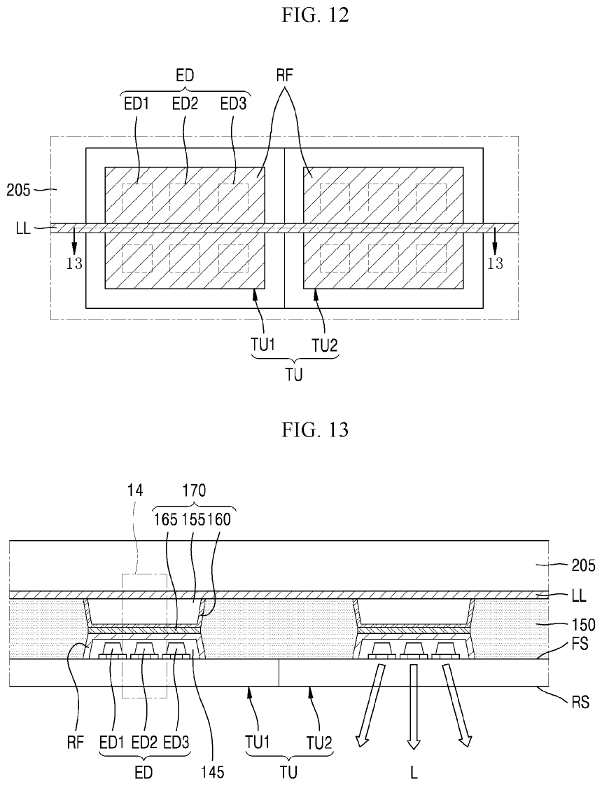

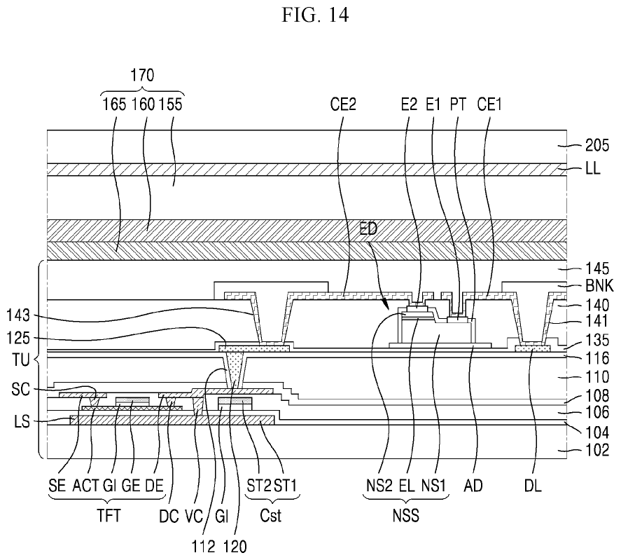

FIG. 12 is a schematic enlarged plan view showing a configuration in which a plurality of display units are disposed on a wiring substrate. FIG. 13 is a cross-sectional view taken along line 13-13 of FIG. 12. FIG. 14 is an enlarged cross-sectional view of an area 14 in FIG. 13. In this regard, since the display unit TU of FIG. 12 to FIG. 14 is the same as the display unit TU according to FIG. 5, the same components may be briefly described or descriptions thereof may be omitted.

Referring to FIG. 12 to FIG. 14, the wiring substrate 205 and the plurality of display units TU1 and TU2 may be bonded and electrically connected to each other via the bonding member 170. A sub-pixel including the light-emitting element ED and the thin-film transistor TFT for driving the light-emitting element ED may be disposed in each of the first display unit TU1 and the second display unit TU2.

In the first display unit TU1 and the second display unit TU2, the sealing layer 145 as a top layer may be exposed. The bonding member 170 may overlap the link wire line LL on the wiring substrate 205. The bonding member 170 may include the spacer pattern 155, the conductive connection pattern 160, and the adhesive pattern 165.

The spacer pattern 155 of the bonding member 170 may have a reverse taper shape in which the upper surface thereof in contact with the link wire line LL is wider than the lower surface thereof. The outer side surface and the lower surface of the spacer pattern 155 may be covered with the conductive connection pattern 160. The conductive connection pattern 160 may cover the lower surface of the spacer pattern 155 while surrounding the outer surface of the spacer pattern 155. The adhesive pattern 165 may be disposed under the conductive connection pattern 160 covering the lower surface of the spacer pattern 155.

The adhesive pattern 165 may be in contact with the exposed sealing layer 145 as a top layer of each of the first display unit TU1 and the second display unit TU2. The adhesive pattern 165 may bond and fix the wiring substrate 205 and the display units TU1 and TU2 to each other, and may have electrical conductivity to transmit a signal transmitted to the link wire line LL on the wiring substrate 205 to the display units TU1 and TU2. Moreover, the adhesive pattern 165 may include a metal material with high reflectance.

For example, the adhesive pattern 165 may be formed in a dotting scheme using a silver (Ag) paste. The bonding member 170 including the adhesive pattern 165 may be disposed on the sealing layer 145 of the display unit TU. An area size of the bonding member 170 may increase such that a size of a contact area between the bonding member 170 and the link wire line LL may increase. Accordingly, a stable bonding force between the display unit TU and the wiring substrate 205 may be maintained.

Moreover, the adhesive pattern 165 may be in contact with the exposed sealing layer 145 as the top layer of each of the first display unit TU1 and the second display unit TU2. The adhesive pattern 165 may include a metal material with high reflectance such as the silver (Ag) paste. Thus, the adhesive pattern 165 may serve as a reflective layer.

Under this configuration, the light emitted from the light-emitting element ED is reflected from the adhesive pattern 165 of the bonding member 170 disposed on the sealing layer 145 to be directed toward the rear surface RS opposite to the front surface FS of the display unit TU, and then may be emitted to the outside. Accordingly, the path along which the light L emitted from the front surface FS of the display unit TU is directed to the wiring substrate 205 may be changed to a path along which the light is directed toward the rear surface RS, as shown in FIG. 13. Thus, the amount of light directed toward the rear surface thereof may be increased such that the light efficiency may be improved.

According to an aspect of the present disclosure, the plurality of display units may be disposed on the upper surface of the wiring substrate and may be arranged to overlap the upper surface of the wiring substrate, such that a transparent display device with a large area may be implemented.

Moreover, the wiring substrate and each of the plurality of display units are electrically connected and are bonded to each other using the bonding member. Thus, a plurality of processes for forming a side surface line may be omitted such that the process optimization may be realized.

Moreover, the reflective layer or the spacer pattern including a metal material with high reflectance may be disposed on top of the display unit. Thus, the light may be directed toward the display unit such that the reflectance of the external light may be reduced. Accordingly, the light efficiency of the display device may be improved.

Although the aspects of the present disclosure have been described in more detail with reference to the accompanying drawings, the present disclosure is not necessarily limited to these aspects, and may be modified in a various manner within the scope of the technical spirit of the present disclosure. Accordingly, the aspects as disclosed in the present disclosure are intended to describe rather than limit the technical idea of the present disclosure, and the scope of the technical idea of the present disclosure is not limited by these aspects. Therefore, it should be understood that the aspects described above are not restrictive but illustrative in all respects.

It will be apparent to those skilled in the art that various modifications and variations can be made in the display device of the present disclosure without departing from the spirit or scope of the aspects of the present disclosure. Thus, it is intended that the present disclosure covers the modifications and variations of the aspects provided they come within the scope of the appended claims and their equivalents.

What is claimed is:

1. A display device comprising:
a wiring substrate on which a plurality of link wire lines are disposed;
a plurality of display units including a plurality of light-emitting elements and a plurality of signal lines, wherein the plurality of display units are disposed on the wiring substrate and spaced apart from each other;
a reflective layer positioned between the wiring substrate and the plurality of display units; and
a plurality of bonding members positioned between the reflective layer and the wiring substrate and electrically connecting the plurality of link wire lines and the plurality of signal lines to each other.

2. The display device of claim 1, wherein the wiring substrate includes a single substrate, wherein the plurality of display units are disposed on the wiring substrate and spaced apart from each other in each of transverse and longitudinal directions of the wiring substrate.

3. The display device of claim 1, wherein each of the plurality of bonding members includes:
a spacer pattern having a lower surface in contact the reflective layer;
a conductive connection pattern covering upper and outer side surfaces of the spacer pattern; and
an adhesive pattern disposed on the conductive connection pattern and connected to the link wire line.

4. The display device of claim 3, wherein the spacer pattern has a taper shape in which a width of the lower surface thereof in contact with the reflective layer is larger than a width of an upper surface thereof in contact with the link wire line.

5. The display device of claim 3, wherein the spacer pattern has a reverse taper shape in which a width of the lower surface in contact with the reflective layer is smaller than a width of an upper surface thereof in contact with the link wire line.

6. The display device of claim 3, further comprising a sealing layer as a top layer thereof, wherein the reflective layer is in contact with the sealing layer.

7. The display device of claim 3, further comprising a sealing layer as a top layer thereof, wherein the adhesive pattern is in contact with the sealing layer.

8. The display device of claim 7, wherein the adhesive pattern includes a silver paste.

9. The display device of claim 3, wherein the spacer pattern and the reflective layer are made of a same material.

10. The display device of claim 1, wherein the display device further comprises a filler disposed between the wiring substrate and the display units,
wherein the filler includes a transparent resin.

11. The display device of claim 1, further comprising:
a circuit film disposed at at least one side end of the wiring substrate, and connected to the link wire line;
an integrated circuit chip mounted on the circuit film for transmitting a driving signal to the plurality of display units; and
a printed circuit board connected to the circuit film.

12. The display device of claim 1, wherein the plurality of link wire lines are disposed to respectively overlap each of the plurality of display units.

13. The display device of claim 3, wherein the spacer pattern includes a metal material having high reflectance.
